(19) United States
(12) Patent Application Publication
(10) Pub. No.: US 2012/0126843 A1
(43) Pub. Date: May 24, 2012

(54) PROBE CARD HOLDING APPARATUS AND PROBER

(75) Inventor: Satoshi Shibahara, Saitama (JP)

(73) Assignee: ADVANTEST CORPORATION, Tokyo (JP)

(21) Appl. No.: 13/384,815

(22) PCT Filed: Jul. 30, 2009
(86) PCT No.: PCT/JP2009/063587

§ 371 Date: Jan. 19, 2012

(51) Int. Cl. G01R 31/00

(52) U.S. Cl. 324/756.03

(57) ABSTRACT

A probe card holding apparatus which is provided at a prober and holds a probe card includes: a clamp mechanism which clamps a clamp head which is formed at the probe card; a clamp bar which is laid over an opening of the prober in which the probe card is inserted; and an elevator device which is provided at the clamp bar and moves up and down the clamp mechanism.

### TECHNICAL FIELD

The present invention relates to a probe card holding apparatus which holds a probe card and to a prober comprising the same.

### BACKGROUND ART

A probe card which is used in a test of a semiconductor integrated circuit device or other device under test (DUT) which is formed into a semiconductor wafer is attached via a holder to an opening formed on a top plate of a prober. In such a probe card, to increase the number of devices which can be simultaneously measured (number of DUTs which can be simultaneously tested) or to enlarge the mounting area of relays and other electronic devices used for the tests, the probe card itself has to be made larger in size.

### SUMMARY OF INVENTION

### Technical Problem

However, if making a probe card larger in size, there is the problem that space for interposing the holder between the opening of the top plate and the probe card cannot be sometimes secured in existing probers.

The problem to be solved by the present invention is the provision of a probe card holding apparatus which can attach a large-sized probe card to an existing prober and the provision of a prober comprising the same.

### Solution to Problem

According to the present invention, there is provided a probe card holding apparatus which is provided at a prober and which holds a probe card, the probe card holding apparatus characterized by comprising: a clamp mechanism which clamps a projecting part which is formed at the probe card; a beam member which is laid over an opening of the prober in which the probe card is inserted; and an elevating means which is provided at the beam member and moves up and down the clamp mechanism (see claim 1).

While not particularly limited in the invention, preferably the clamp mechanism can be moved up and down by the elevating means in a state clamping the projecting part (see claim 2).

While not particularly limited in the invention, preferably the clamp mechanism can be moved down into the opening by the elevating means (see claim 3).

While not particularly limited in the invention, preferably the clamp mechanism has: a first tube-shaped member which has an engagement part which can engage with the projecting part and which is moved up and down by the elevating means; and a second tube-shaped member in which the first tube-shaped member is inserted to be able to move in the axial direction, and the beam member has a recess in which the second tube-shaped member is inserted to be able to move in the axial direction (see claim 4).

While not particularly limited in the invention, preferably the engagement part sticks out from the inner circumferential surface of the first tube-shaped member toward an engagement groove which is formed in the projecting part due to relative movement of the first tube-shaped member with respect to the second tube-shaped member (see claim 5).

While not particularly limited in the invention, preferably the engagement part is a spherical member which is accommodated in a holding hole which is formed in a wall surface of the first tube-shaped member, and part of the spherical member sticks out from the holding hole toward the groove due to relative movement of the first tube-shaped member with respect to the second tube-shaped member (see claim 6).

While not particularly limited in the invention, preferably the first tube-shaped member has: a first tubular part which has a first inside hole which can accommodate the projecting part; and a first top lid part which closes the top end of the first tubular part, and the first top lid part can abut against the projecting part (see claim 7).

While not particularly limited in the invention, preferably the elevating means has: an actuator which makes a drive shaft extend and retract; a cam plate which is attached to the front end of the drive shaft and in which a cam is formed, a cam follower which follows the cam; and a connecting member to the top end of which the cam follower is attached and to the bottom end of which the first top lid part is attached (see claim 8).

While not particularly limited in the invention, preferably the second tube-shaped member has: a second tubular part which has a second inside hole which can accommodate the first tube-shaped member; and a second top lid part which closes the top end of the second tubular part, and a through hole through which the connecting member is inserted is formed in the second top lid part (see claim 9).

Further, according to the present invention, there is provided a prober characterized comprising: the above probe card holding apparatus; and a top plate in which an opening is formed for insertion of the probe card and at which the probe card holding apparatus is provided (see claim 10).

### ADVANTAGEOUS EFFECTS OF INVENTION

In the present invention, an elevating means is provided at a beam member which is laid over an opening of the prober and that elevating means can be used to move up and down the clamp mechanism, so it is possible to attach a large-sized probe card to an existing prober without using a holder.

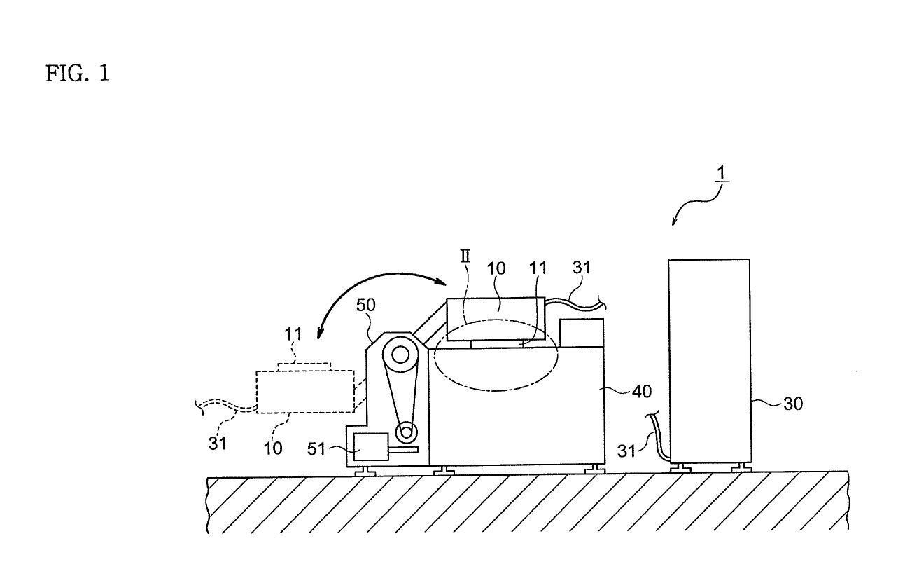

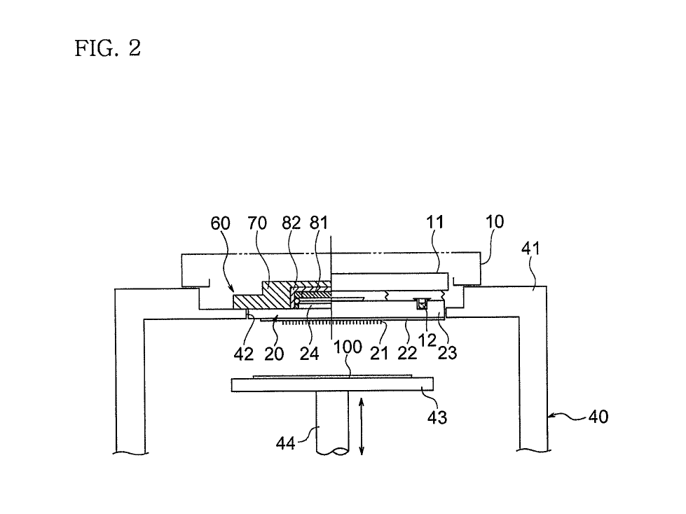

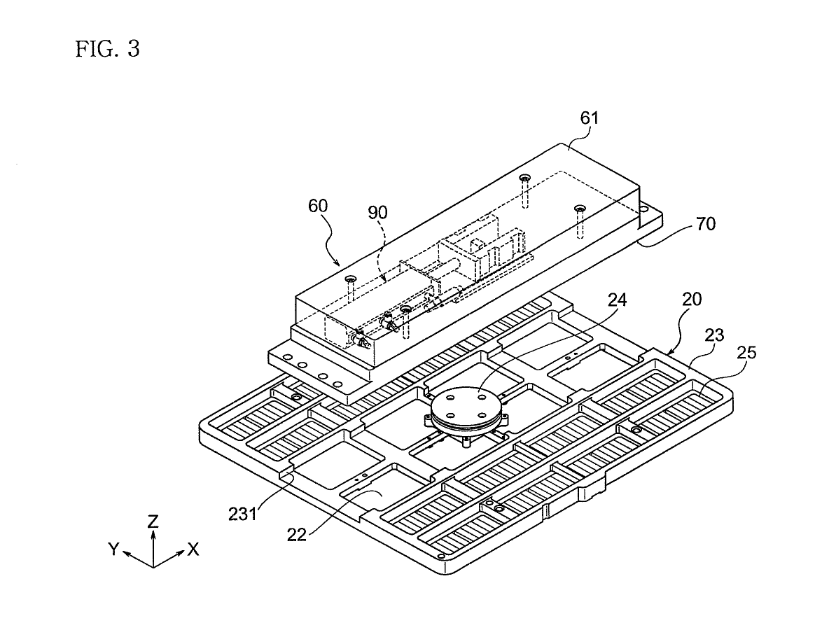

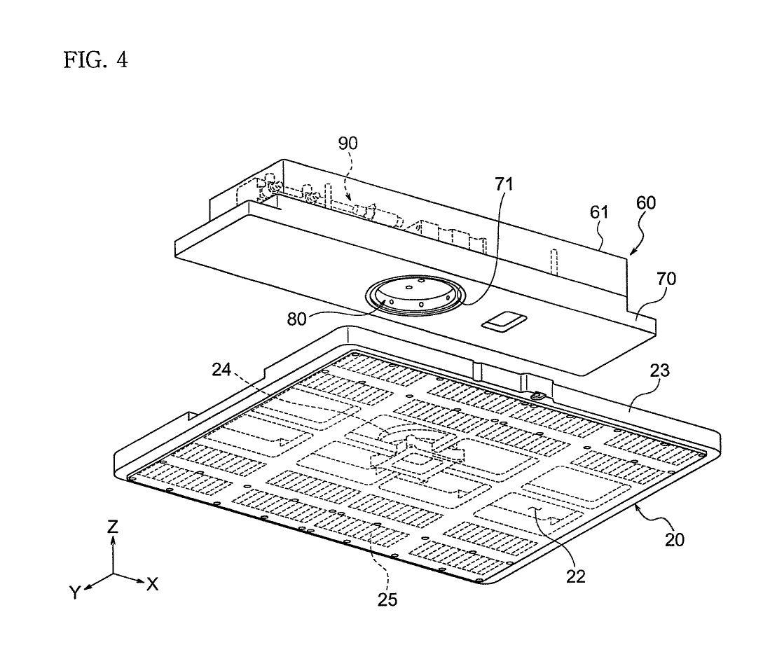

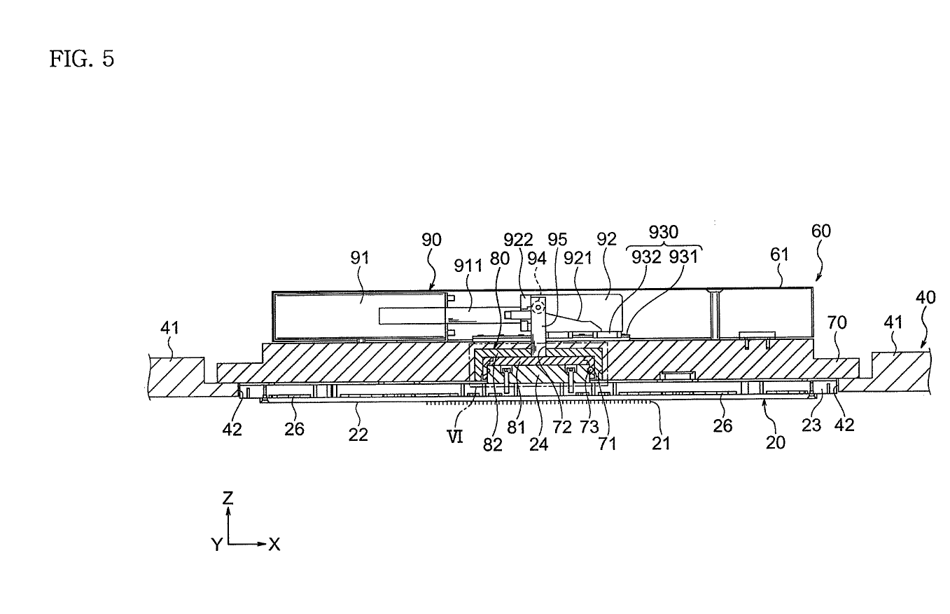

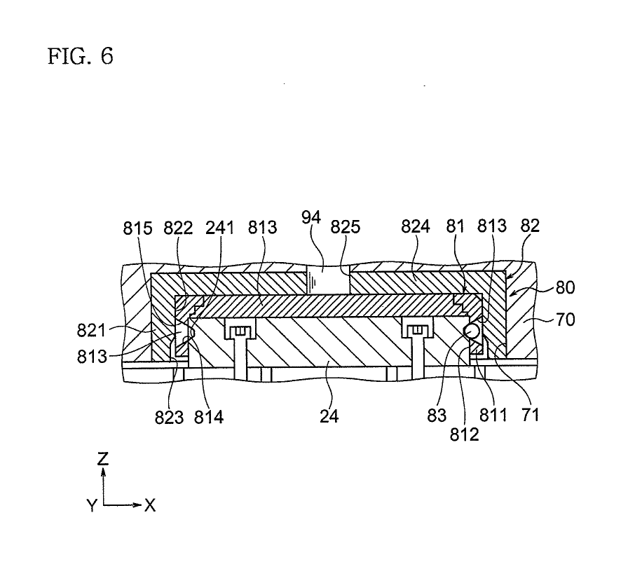

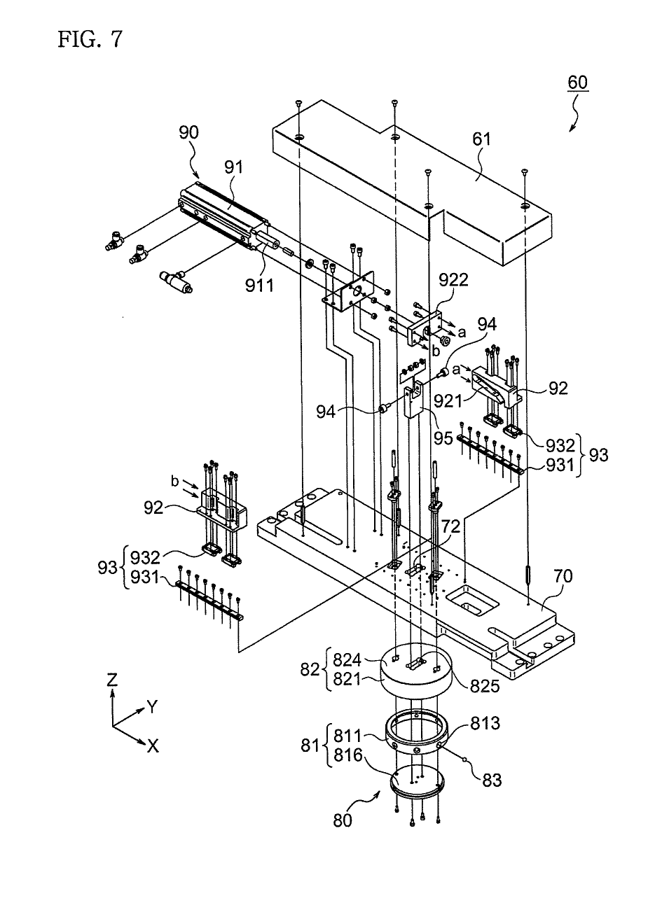

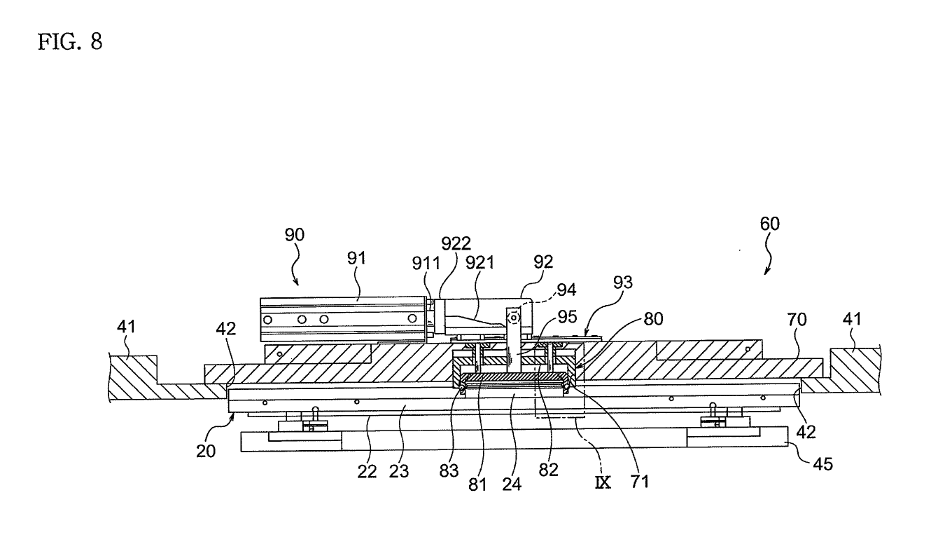

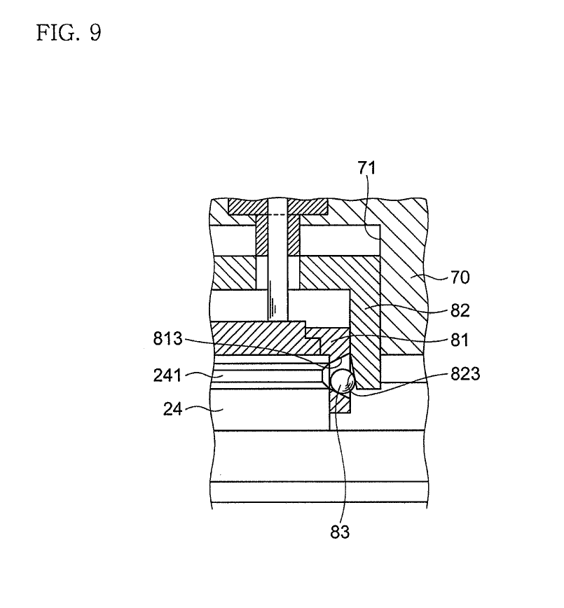

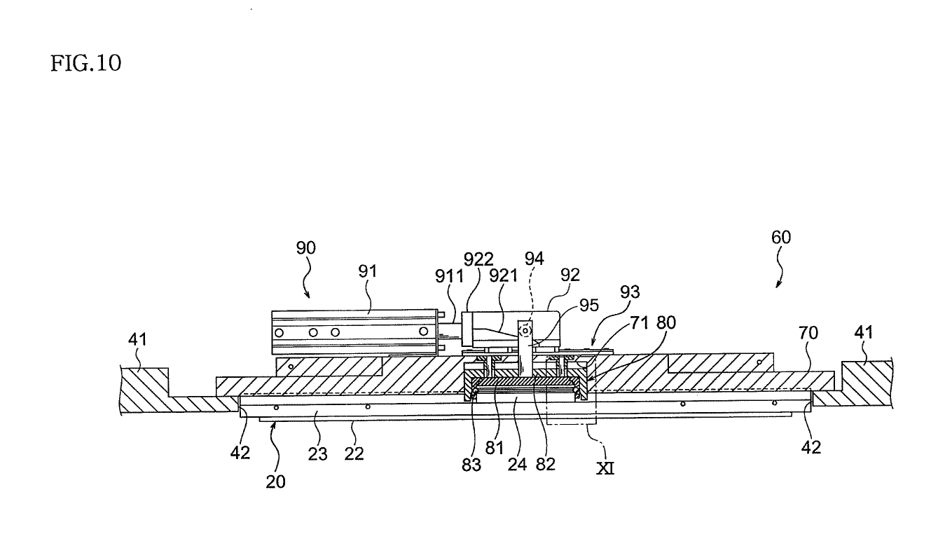

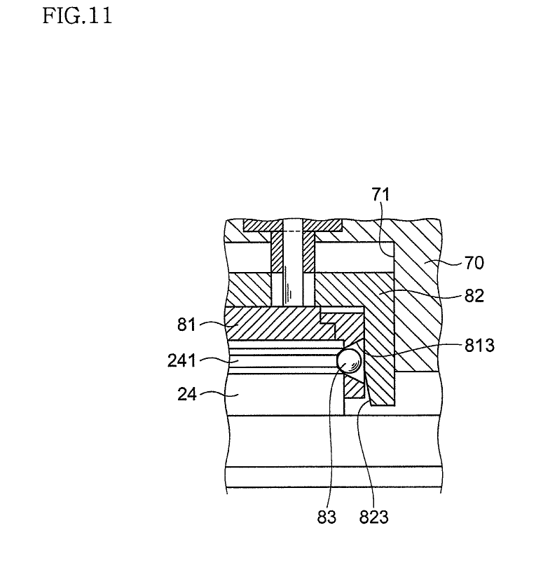

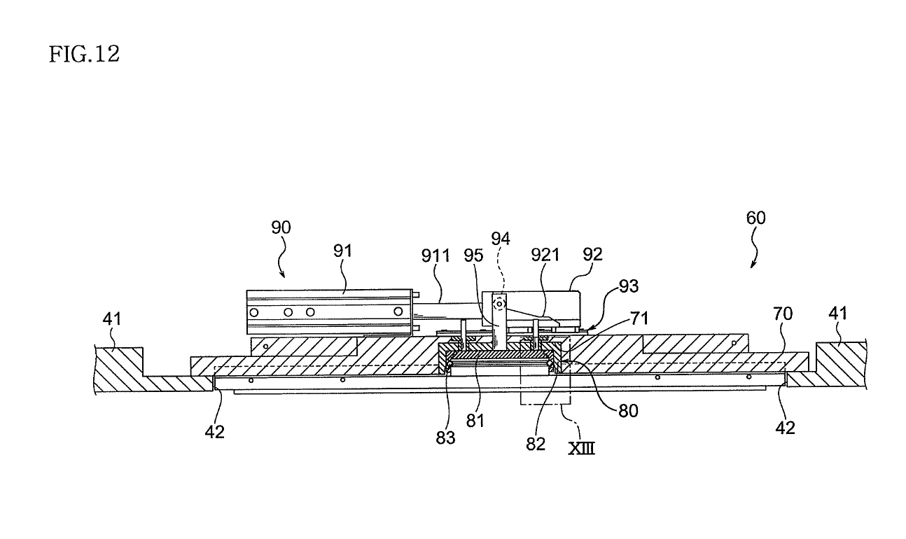

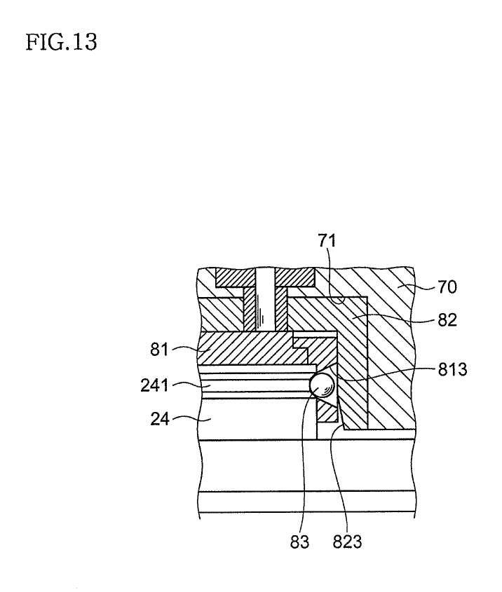

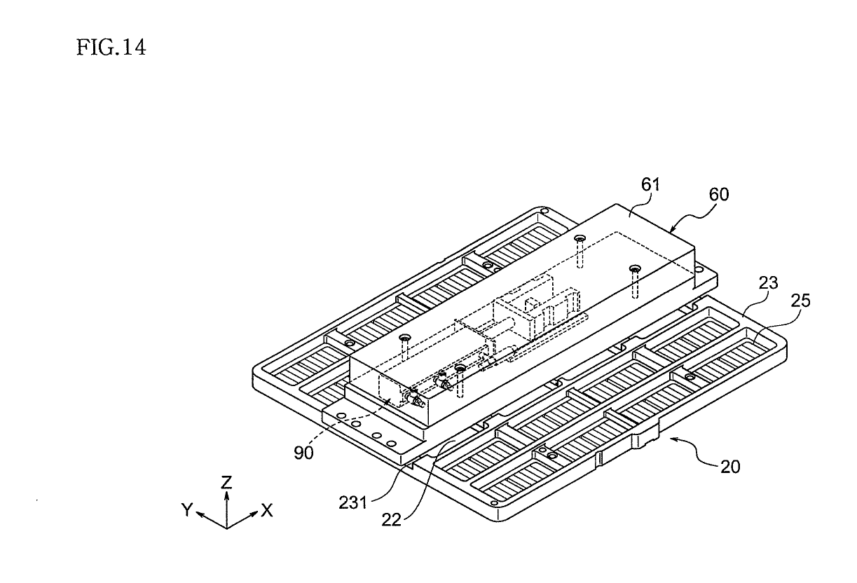

### BRIEF DESCRIPTION OF DRAWINGS

[FIG. 1] FIG. 1 is a schematic side view showing an electronic device test apparatus in an embodiment of the present invention.

[FIG. 2] FIG. 2 is an internal enlarged view of a part II of FIG. 1.

[FIG. 3] FIG. 3 is a perspective view showing a probe card and probe card holding apparatus in an embodiment of the present invention.

[FIG. 4] FIG. 4 is a perspective view of the probe card and probe card holding apparatus shown in FIG. 3 as seen from the bottom.

[FIG. 5] FIG. 5 is a cross-sectional view of a probe card holding apparatus in an embodiment of the present invention.

[FIG. 6] FIG. 6 is an enlarged view of a part VI of FIG. 5.

[FIG. 7] FIG. 7 is a disassembled perspective view of a probe card holding apparatus in an embodiment of the present invention.

[FIG. 8] FIG. 8 is a cross-sectional view showing the operation of a probe card holding apparatus in an embodiment of the present invention (part 1).

[FIG. 9] FIG. 9 is an enlarged view of a part IX of FIG. 8.

[FIG. 10] FIG. 10 is a cross-sectional view showing the operation of a probe card holding apparatus in an embodiment of the present invention (part 2).

[FIG. 11] FIG. 11 is an enlarged view of a part XI of FIG. 10.

[FIG. 12] FIG. 12 is a cross-sectional view showing the operation of a probe card holding apparatus in an embodiment of the present invention (part 3).

[FIG. 13] FIG. 13 is an enlarged view of a part XIII of FIG. 12.

[FIG. 14] FIG. 14 is a perspective view showing the state where a probe card holding apparatus holds a probe card in an embodiment of the present invention.

### DESCRIPTION OF EMBODIMENTS

Below, embodiments of the present invention will be explained based on the drawings.

FIG. 1 is a schematic side view showing an electronic device test apparatus in an embodiment of the present invention, FIG. 2 is an internal enlarged view of a part II of FIG. 1, FIG. 3 and FIG. 4 are perspective views showing a probe card and probe card holding apparatus in the present embodiment, FIG. 5 is a cross-sectional view of a probe card holding apparatus in an embodiment of the present invention, FIG. 6 is an enlarged view of a part VI of FIG. 5, and FIG. 7 is a disassembled perspective view of a probe card holding apparatus in an embodiment of the present invention.

The electronic device test apparatus 1 in the present embodiment is an apparatus which tests the electrical characteristics of DUTs which are formed into a semiconductor wafer 100. As shown in FIG. 1, it comprises a test head 10, a tester 30, and a prober 40. In this electronic device test apparatus 1, the prober 40 pushes the semiconductor wafer 100 against a probe card 20 which is attached to the test head 10. The tester 30 which is connected through a cable 31 to the test head 10 inputs and outputs test signals with the DUTs so as to test the DUTs. Incidentally, the test head 10 is inverted by a manipulator 50 and drive motor 51 from the maintenance position (shown by broken line in FIG. 1) over the top plate 4 of the prober 40.

As shown in FIG. 2, a HIFIX 11 is attached to the bottom of the inverted test head 10. This HIFIX 11 has a probe card 20 attached to it for electrical contact with the DUTs on the semiconductor wafer 100. For this reason, connectors (not shown) which engage with connectors 25 of the probe card 20 (FIG. 3) and a lock mechanism 12 which pulls the probe card 20 toward the HIFIX 11 and fastens it so as to enable reliable engagement of these connectors are provided at the bottom surface of this HIFIX 11.

The probe card 20 in the present embodiment, as shown in FIG. 2 to FIG. 5, comprises probe pins 21, a circuit board 22, a stiffener 23, and a clamp head 24.

The probe pins 21 are contactors for electrical contact with the input/output terminals of the DUTs on the semiconductor wafer 100 and specifically comprises pogo pins or needles etc. Note that, in FIG. 4, illustration of the probe pins 21 is omitted.

The circuit board 22 in the present embodiment has a rectangular shape as a whole. A large number of probe pins 21 are attached to the center part of its bottom surface. A frame shaped stiffener 23 is attached to the top surface of the circuit board 22. Further, connectors 25 for electrically connecting this probe card 20 to the HIFIX 11 (FIG. 3) and relays and other various electronic devices 26 which are used for testing the DUTs (FIG. 5) are mounted on the parts of the top surface of the circuit board 22 which are surrounded by the stiffener 23.

The clamp head 24 is a disk shaped member which is provided at the substantial center of the stiffener 23. As shown in FIG. 6, an engagement groove 241 with which the probe card holding apparatus 60 engages is formed at the top of the circumferential surface of this clamp head 24. Further, as shown in FIG. 3, a recess 231 in which part of the clamp bar 70 of the probe card holding apparatus 60 may enter is formed at the center of the stiffener 23 in a traversing manner.

In the present embodiment, the circuit board 22 is made rectangular in shape whereby a greater number of probe pins 21 can be mounted, so an increase in the number of simultaneous measurements can be handled. Further, by making the circuit board 22 rectangular in shape, it is possible to secure a broader mounting area for the electronic devices 26 required for testing.

The above explained probe card 20 is inserted into an opening 42 formed in the top plate 41 of the prober 40 in the state held by the probe card holding apparatus 60 of the prober 40.

The prober 40 comprises:, in addition to this probe card holding apparatus 60, as shown in FIG. 2, a suction stage 43 on which the semiconductor wafer 100 is held by suction; a conveyor arm 44 which moves this suction stage 43 in the XYZ directions and rotates it about a Z-axis; and an exchange arm 45 which exchanges probe cards 20 positioned at the opening 42 of the top plate 41 (FIG. 8).

At the time of the test, the conveyor arm 44 moves the semiconductor wafer 100 held on the suction stage 43 to face the probe card 20 positioned inside the prober 40 via the opening 42. The wafer 100 is pushed against the probe card 20 to make the probe pins 21 electrically contact the input/output terminals of the DUTs. In this state, the tester 30 inputs test signals to the DUTs through the test head 10, receives response signals from the DUTs, and compares the response signals with predetermined anticipated values so as to evaluate the electrical characteristics of the DUTs.

The probe card holding apparatus 60 in the present embodiment, as shown in FIG. 5, comprises: a clamp bar 70 which is laid over the opening 42 of the top plate 41; a clamp mechanism 80 which clamps the clamp head 24 of the probe card 20; and an elevator device 90 which is provided at the clamp bar 70 and moves up and down the clamp mechanism 80.

The clamp bar 70 of the probe card holding apparatus 60 is a substantially plate shaped beam member which is provided at the top plate 41 of the prober 40 so as to straddle the opening 42 in which the probe card 20 is inserted. Note that, while not particularly shown, this clamp bar 70 is fastened at its two ends by bolts etc. to the peripheral edges of the opening 42 in the top plate 41.

As shown in FIG. 4 to FIG. 6, a circular cross-section recess 71 which accommodates the clamp mechanism 80 is formed at the substantial center of the bottom surface of the clamp bar 70. Further, as shown in FIG. 5 and FIG. 7, a through hole 72 into which the connecting member 95 of the elevator device 90 is inserted is formed between the top surface of the clamp bar 70 and the recess 71.

The clamp mechanism 80 of the probe card holding apparatus 60, as shown in FIG. 5 to FIG. 7, comprises: a first closed lid tubular member 81 of a tubular shape having a top lid; and a second closed lid tubular member 82 of a tubular shape having a top lid.

The first closed lid tubular member 81 has: a first tubular part 811 which has a first inside hole 812; and a first top lid part 816 which closes the top end of the first tubular part 811.

The first inside hole 812 of the first tubular part 811 can accommodate a clamp head 24 of the probe card 20. Further, this first tubular part 811 is formed with eight holding holes 813 at substantially equal distances along the peripheral direction. These holding holes 81 accommodate steel balls 83. Note that, the number of holding holes 813 which are formed in the first tubular part 811 is not particularly limited. Further, in FIG. 5 and FIG. 6, to facilitate illustration of the holding hole 81 itself, the holding hole 81 which is positioned at the left side in the figure is shown without a steel ball 83.

As shown in FIG. 6, these holding holes 813 have: inside openings 814 which open to the first inside hole 812; and outside openings 815 which open toward the outside (toward the second closed lid tubular member 82).

Each inside opening 814 has an inside diameter which is smaller than the diameter of the steel ball 83. Only part of the steel ball 83 can stick out from the inside opening 814. On the other hand, each outside opening 815 has an inside diameter larger than the diameter of the steel ball 83. For this reason, part of the steel ball 83 can be retracted from the outside opening 815 to the taper part 823 of the second closed lid tubular member 82.

Further, a bottom end of the connecting member 95 of the elevator device 90 is fastened to the first top lid part 816. The elevator device 90 can move up and down the first closed lid tubular member 82. This first top lid part 816 closely contacts the top surface of the clamp head 24 when the clamp head 24 is accommodated in the first inside hole 812. For this reason, when the semiconductor wafer 100 is pushed against the probe card 20, deformation of the probe card 20 accompanied by the pushing force is suppressed.

The second closed lid tubular member 82 has: a second tubular part 821 which has a second inside hole 822; and a second top lid part 824 which closes the top end of the second tubular part 821, and is accommodated in the recess 71 of the clamp bar 70 in a manner movable in the axial direction.

The first closed lid tubular member 81 is accommodated in the second inside hole 822 of the second tubular part 821 in a manner movable in the axial direction. Further, as shown in FIG. 6, a taper part 823 extending in a slanted surface or curved state is formed at the bottom end of the inner circumference of the second tubular part 821 across the entire circumference. The inside diameter of the second inside hole 822 increases the closer to the opening. Note that, it is also possible to form the taper part 823 at only the positions corresponding to the holding holes 813 of the first closed lid tubular member 81.

A through hole 825 in which a connecting member 95 of the elevator device 90 is inserted in a manner movable in the axial direction is formed in the second top lid part 824. The first closed lid tubular member 81 and the second closed lid tubular member 82 are able to move up and down in a nested state.

That is, in the state where the first and second top lid parts 816, 824 are not in contact, the first closed lid tubular member 81 can move up and down relative to the second closed lid tubular member 82 (see FIG. 8 and FIG. 9). On the other hand, in the state where the first and second top lid parts 816, 824 are in contact, if the elevator device 90 operates, the first closed lid tubular member 81 and the second closed lid tubular member 82 can integrally move up and down (see FIG. 10 and FIG. 11).

Further, if the first closed lid tubular member 81 moves up relative to the second closed lid tubular member 82, the steel balls 83 which were retracted in the taper part 823 are pushed back to the inside along with the reduction in inside diameter of the second closed lid tubular member 82 and partially stick out from the inside openings 814 of the holding holes 813. Further, the steel balls 83 engage with the engagement groove 241 of the clamp head 24 of the probe card 20, so the clamp head 24 is clamped by the clamp mechanism 80.

The elevator device of the probe card holding apparatus 60, as shown in FIG. 5 and FIG. 7, comprises an actuator 91, a pair of cam plates 92, a linear guide 93, cam followers 94, and a connecting member 95. Such an elevator device 90 is provided on the clamp bar 70 and is covered by a cover member 61 such as shown in FIG. 7.

The actuator 91 comprises an air cylinder which makes a drive shaft 911 extend and retract. This actuator 91 is set on the clamp bar 70 so that the drive shaft 911 faces the substantial center of the clamp bar 70. The pair of cam plates 92 are attached to the front end of this drive shaft 911 through a block member 922. Note that, the actuator of the elevator device may, for example, comprises a motor and a ball and screw mechanism etc.

Each of the cam plates 92 is provided at the clamp bar 70 so as to be able to slide via the linear guide 93. The linear guide 93 comprises: a pair of guide rails 931 which are provided along the X-direction so as to sandwich the through hole 72 of the clamp bar 70 between them; and a slide block 932 which can slide over the guide rails 931. The cam plates 92 are fastened to the slide block 932. By the slide block 932 sliding on the guide rails 931, the cam plates 92 can move along the drive direction of the actuator 91.

The cam plates 92 are formed with cams 921 which the cam followers 94 follow. On the other hand, the cam followers 94 are attached to the both side surfaces of the connecting member 95 in a rotatable manner. The connecting member 95 is sandwiched between the pair of cam plates 92. The two cam followers 94 are both held on the cams 921.

The connecting member 95, as explained above, is inserted in the through hole 72 of the clamp bar 70 in a manner able to move up and down. The second closed lid tubular member 82 of the clamp mechanism 80 is fastened to the bottom end of it.

Next, the operation of the probe card holding apparatus 60 holding the probe card 20 in the present embodiment will be explained.

FIG. 8 to FIG. 13 are cross-sectional views showing the operation of the probe card holding apparatus in the present embodiment, while FIG. 14 is a perspective view showing the state of the probe card holding apparatus holding the probe card in the present embodiment.

As shown in FIG. 8, when the exchange arm 45 of the prober 40 loads the probe card 20 to a predetermined height, first, the air cylinder 91 of the elevator device 90 shortens the drive shaft 911 to move down the clamp mechanism 80 to the lower limit. That is, the second closed lid tubular member 82 is made to stick out to the maximum extent from the recess 71 of the clamp bar 70 while the first closed lid tubular member 81 is made to stick out to the maximum extent from the second inside hole 822 of the second closed lid tubular member 82.

In this state, the first closed lid tubular member 81 moves down to the inside of the opening 42 of the top plate 41, whereupon the clamp head 24 is accommodates in the first tubular part 811 of the first closed lid tubular member 81. Incidentally, in this state, as shown in FIG. 9, the steel balls 83 are partially retracted in the taper parts 823 of the second closed lid tubular member 82 and do not stick out from the inside openings 813 of the holding holes 813.

Next, as shown in FIG. 10, the air cylinder 91 of the elevator device 90 makes the drive shaft 911 extend whereby the first closed lid tubular member 81 moves up relative to the second closed lid tubular member 82 and the first closed lid tubular member 81 is completely accommodated in the second inside hole 822. At this time, as shown in FIG. 11, the steel balls 83 are pushed back by the second closed lid tubular member 82 and partially stick out from the inside openings 814 of the holding holes 813. Due to this, parts of the steel balls 83 enter into the engagement groove 241 of the clamp head 24 of the probe card 20, so the clamp head 24 is clamped by the clamp mechanism 80 and the top surface of the clamp head 24 of the probe card 20 closely contacts the first top lid part 816.

In this way, in the present embodiment, the probe card 20 which is supplied by the exchange arm 45 to a predetermined height is clamped by the clamp mechanism 80 of the probe card holding apparatus 60, so the clamp mechanism 80 is moved up to the opening 42 by the elevator device 90. Therefore, there is no need for a holder for holding the probe card 20 at the prober 40.

Next, as shown in FIG. 12, the air cylinder 91 of the elevator device 90 makes the drive shaft 911 further extend. Due to this, in the state where the clamp mechanism 80 clamps the probe card 20, this is moved up by the elevator device 90. As shown in FIG. 13, the second closed lid tubular member 82 is completely accommodated in the recess 71 and the HIFIX 11 in the floating state is pushed up somewhat.

Next, if locking the lock mechanism 12 of the HIFIX 11, the HIFIX 11 is pulled toward the probe card 20 whereby the connectors engage and, as shown in FIG. 14, the probe card holding apparatus 60 holds the probe card 20. Note that, it is also possible to not provide the HIFIX 11 with a lock mechanism 12 but to utilize the ascending and descending action of the clamp mechanism 80 by the elevator device 90 so as to engage the connectors of the HIFIX 11 and the connectors 25 of the probe card 20.

In this way, in the present embodiment, the clamp bar 70 which is provided over the opening 42 of the prober 40 is provided with an elevator device 90. Due to the elevator device 90, the clamp mechanism 80 is made to ascend and descend, so it is possible to attach a large sized probe card to an existing prober without using a holder.

In particular, in the present embodiment, the clamp bar 70 is provided at the top plate 41 to straddle the opening 42, so it is possible to suppress deformation of the probe card 20 when pushing against the semiconductor wafer 100.

Further, in the present embodiment, the recess 71 of the clamp bar 70 and the first and second closed lid tubular members 81, 82 of the clamp mechanism 80 form a nested structure, so it is possible to reduce the total thickness of the probe card holding apparatus 60 at the time of holding the probe card.

Further, when the first and second closed lid tubular members 81, 82 are completely accommodated in the recess 71 of the clamp bar 70 by such a nested structure, the bottom surface of the clamp bar 71 closely contacts the stiffener of the probe card 20. For this reason, when pushing against the semiconductor wafer 100, the pushing force can be received by the clamp bar 71 as a whole, so deformation of the probe card 20 can be further suppressed.

Further, in the present embodiment, a single actuator 91 is used to clamp the clamp mechanism 80 and elevate the clamp mechanism 80, so the structure of the probe card holding apparatus 60 is simplified.

Note that the embodiments explained above were described for facilitating understanding of the present invention and were not described for limiting the present invention. Therefore, the elements disclosed in the above embodiments include all design modifications and equivalents falling under the technical scope of the present invention.

### REFERENCE SIGNS LIST

10 test head
11 HIFIX
20 probe card
24 clamp head (projecting part)
241 engagement groove
40 prober
41 top plate
42 opening
60 probe card holding apparatus
61 cover member
70 clamp bar (beam member)
71 recess
80 clamp mechanism
81 first closed lid tubular member
811 first tubular part
816 first top lid part
82 second closed lid tubular member
821 second tubular part
823 taper part
824 second top lid part
83 steel ball
90 elevator device
91 air cylinder
911 drive shaft
92 cam plate
94 cam follower
95 connecting member

1. A probe card holding apparatus which is provided at a prober and which holds a probe card, comprising:
a clamp mechanism which clamps a projecting part which is formed at the probe card;
a beam member which is laid over an opening of the prober in which the probe card is inserted; and
an elevator which is provided at the beam member and moves up and down the clamp mechanism.

2. The probe card holding apparatus as set forth in claim 1, wherein the clamp mechanism can be moved up and down by the elevator in a state clamping the projecting part.

3. The probe card holding apparatus as set forth in claim 1, wherein the clamp mechanism can be moved down into the opening by the elevator.

4. The probe card holding apparatus as set forth in claim 1, wherein
the clamp mechanism has:
a first tube-shaped member which has an engagement part which can engage with the projecting part and which is moved up and down by the elevator; and
a second tube-shaped member in which the first tube-shaped member is inserted to be able to move in the axial direction, and
the beam member has a recess in which the second tube-shaped member is inserted to be able to move in the axial direction.

5. The probe card holding apparatus as set forth in claim 4, wherein the engagement part sticks out from the inner circumferential surface of the first tube-shaped member toward an engagement groove which is formed in the projecting part due to relative movement of the first tube-shaped member with respect to the second tube-shaped member.

6. The probe card holding apparatus as set forth in claim 5, wherein
the engagement part is a spherical member which is accommodated in a holding hole which is formed in a wall surface of the first tube-shaped member, and
part of the spherical member sticks out from the holding hole toward the groove due to relative movement of the first tube-shaped member with respect to the second tube-shaped member.

7. The probe card holding apparatus as set forth in claim 4, wherein
the first tube-shaped member has:
a first tubular part which has a first inside hole which can accommodate the projecting part; and
a first top lid part which closes the top end of the first tubular part, and
the first top lid part can abut against the projecting part.

8. The probe card holding apparatus as set forth in claim 7, wherein
the elevator elevating means has:
an actuator which makes a drive shaft extend and retract;
a cam plate which is attached to the front end of the drive shaft and in which a cam is formed;
a cam follower which follows the cam; and
a connecting member to the top end of which the cam follower is attached and to the bottom end of which the first top lid part is attached.

9. The probe card holding apparatus as set forth in claim 8, wherein
the second tube-shaped member has:
a second tubular part which has a second inside hole which can accommodate the first tube-shaped member; and
a second top lid part which closes the top end of the second tubular part, and
a through hole through which the connecting member is inserted is formed in the second top lid part.

10. A prober comprising:
a probe card holding apparatus as set forth in claim 1; and
a top plate in which an opening is formed for insertion of the probe card and at which the probe card holding apparatus is provided.
